(19) United States
(12) Patent Application Publication
(10) Pub. No.: US 2025/0369784 A1
(43) Pub. Date: Dec. 4, 2025

(54) EXCITATION CIRCUIT OF ELECTROMAGNETIC FLOWMETER

(71) Applicant: Azbil Corporation, Tokyo (JP)

(72) Inventors: Kouki YASUTOMI, Tokyo (JP); Osamu MOMOSE, Tokyo (JP)

(73) Assignee: Azbil Corporation, Tokyo (JP)

(21) Appl. No.: 19/213,998

(22) Filed: May 20, 2025

(30) Foreign Application Priority Data
May 28, 2024 (JP) 2024-086367

(51) Int. Cl. G01F 1/60; G01R 19/00; H02M 3/155

(52) U.S. Cl. CPC G01F 1/60; G01R 19/0023; G01R 19/0038; H02M 3/155

(57) ABSTRACT

An excitation circuit of an electromagnetic flowmeter includes: an excitation switching circuit 1 that switches the polarity of an excitation current supplied to an excitation coil L1; diodes D1 and D2 with cathodes connected to a voltage input terminal of the excitation switching circuit 1; a DC/DC converter 2 that supplies a low voltage VexL; a constant current circuit 3 with an input terminal connected to an output terminal of the DC/DC converter 2, and an output terminal connected to an anode of the diode D1; and a switch SW5 with a first contact terminal connected to a high voltage VexH, and a second contact terminal connected to an anode of the diode D2, which turns on during a period from an excitation period start point to a rising point of the excitation current within the excitation period, and turns off during a period from the rising point to an excitation period end point. A feedback voltage to the DC/DC converter 2 is set to an anode side voltage of the diode D1.

### CROSS-REFERENCE TO RELATED APPLICATION

This application claims the priority benefit of Japanese application serial no. 2024-086367, filed on May 28, 2024. The entirety of the above-mentioned patent application is hereby incorporated by reference herein and made a part of this specification.

### TECHNICAL FIELD

The disclosure relates to an excitation circuit of an electromagnetic flowmeter.

### BACKGROUND

An electromagnetic flowmeter includes an excitation coil that generates a magnetic field in a direction perpendicular to the flow direction of a fluid flowing inside a measurement tube, and a pair of detection electrodes that are disposed inside the measurement tube and arranged in a direction orthogonal to the magnetic field generated by the excitation coil. In the electromagnetic flowmeter, the flow rate of the fluid flowing inside the measurement tube is measured by detecting the electromotive force generated between the detection electrodes while alternately switching the polarity of an excitation current flowing through the excitation coil.

Generally, as a method for improving the measurement stability of an electromagnetic flowmeter, it is considered to increase the excitation current to raise the resulting flow signal level S or increase the excitation frequency to reduce the 1/f noise N contained in the flow signal, thereby improving the S/N ratio (Signal to Noise Ratio).

FIG. 5 shows an excitation circuit of an electromagnetic flowmeter disclosed in Patent Document 1 (Japanese Patent No. 6985185). In FIG. 5, 100 is a constant current circuit, 101 is a control circuit that outputs polarity switching signals EXD1 and EXD2 for an excitation current Iex, 102 is an excitation current rising detection circuit, L1 is an excitation coil, A1 is an operational amplifier, Q1 is a power MOS-FET, D1 and D2 are diodes, R1 and R2 are current detection resistors, and SW1 to SW5 are switches. The constant current circuit 100 includes the operational amplifier A1, the power MOS-FET Q1, and the current detection resistor R2.

In the excitation circuit shown in FIG. 5, to accelerate the rising of the excitation current Iex at the time of excitation polarity switching, two power supplies, high voltage VexH and low voltage VexL, are prepared in advance. The excitation circuit is configured to excite with the high voltage VexH at the rising of the excitation current Iex, and to excite with the low voltage VexL at steady state. By switching from this high voltage VexH to low voltage VexL, heat generation of the power MOS-FET Q1 in the constant current circuit 100 is reduced.

Furthermore, in the excitation circuit shown in FIG. 5, the constant current circuit 100 is moved to the low voltage power supply side, and during high-voltage excitation, the configuration directly supplies voltage to the excitation coil L1 without passing through the constant current circuit 100. Thus, even if the applied voltage during high-voltage excitation is increased to be higher than the conventional level, the heat generation of the power MOS-FET Q1 does not increase significantly. Therefore, it becomes possible to accelerate the rising of the excitation current Iex through high-voltage excitation to increase the excitation frequency.

In the excitation circuit shown in FIG. 5, during low-voltage excitation, the switch SW5 is turned off so that the excitation current Iex passes through the power MOS-FET Q1 of the constant current circuit 100. Generally, the power supply that provides the low voltage VexL is a constant voltage power supply. The voltage value VexL of this constant voltage power supply is designed with a margin considering factors such as the DC resistance value of the excitation coil L1. On the other hand, excitation coils L1 of various sizes in diameter are employed depending on the applications for which the electromagnetic flowmeter is used. Since it is necessary to change the specifications such as the number of turns and wire diameter of the excitation coil L1 for each diameter, the DC resistance value of the excitation coil L1 also varies significantly. The DC resistance value of the excitation coil L1 also changes under the influence of heat from the fluid flowing through the excitation coil L1, depending on the temperature of the fluid.

Within the range of possible DC resistance values of the excitation coil L1 as described above, it is necessary to set the low voltage VexL to a relatively high value to be able to supply a predetermined excitation current Iex to the excitation coil L1 with the maximum DC resistance value. In this case, when an excitation coil L1 with a low DC resistance value is connected, the constant current circuit 100 consumes excess power, resulting in the issue of increased heat generation in the power MOS-FET Q1.

FIG. 6A shows the voltage distribution of the drain-source voltage Vd-s of the power MOS-FET Q1 and the voltage Vcoil of the excitation coil L1 when the DC resistance value of the excitation coil L1 is large, and FIG. 6B shows the voltage distribution when the DC resistance value of the excitation coil L1 is small. It should be noted that in FIG. 6A and FIG. 6B, the residual voltage components such as the forward voltage drop of the diode D1 and the voltage drop due to the current detection resistors R1 and R2 are ignored. According to FIG. 6B, when the DC resistance value of the excitation coil L1 is small, the voltage Vcoil of the excitation coil L1 also becomes small, and consequently the drain-source voltage Vd-s of the power MOS-FET Q1 increases, which shows that the heat generation in the power MOS-FET Q1 increases.

The disclosure provides an excitation circuit of an electromagnetic flowmeter that is capable of suppressing heat generation in a component due to a difference in series resistance value of an excitation coil.

### SUMMARY

An excitation circuit of an electromagnetic flowmeter according to the disclosure includes: an excitation switching circuit configured to switch polarity of an excitation current supplied to an excitation coil of the electromagnetic flowmeter to positive polarity/negative polarity for each positive/negative excitation period that is repeated at a constant cycle; a first backflow prevention diode and a second backflow prevention diode with cathodes connected to a voltage input terminal of the excitation switching circuit; a DC/DC converter configured to supply a first voltage; a constant current circuit with an input terminal connected to an output terminal of the DC/DC converter, and an output terminal connected to an anode of the first backflow prevention diode; and a switch with a first contact terminal connected to a second voltage higher than the first voltage, and a second contact terminal connected to an anode of the second backflow prevention diode, and configured to turn on during a period from an excitation period start point to a rising point of the excitation current within the excitation period, and to turn off during a period from the rising point to an excitation period end point, in which a feedback voltage to the DC/DC converter is set to an anode side voltage of the first backflow prevention diode.

Further, in one configuration example of the excitation circuit of the electromagnetic flowmeter according to the disclosure, the constant current circuit includes: a current detection resistor with one end connected to the output terminal of the DC/DC converter; a transistor with a drain connected to the other end of the current detection resistor, and a source connected to the output terminal of the constant current circuit; and an operational amplifier with an output terminal connected to a gate of the transistor, and configured to compare a voltage at the other end of the current detection resistor with a reference voltage, and to control the transistor based on a comparison result obtained.

Additionally, one configuration example of the excitation circuit of the electromagnetic flowmeter according to the disclosure further includes: a rising detection circuit configured to detect the rising point of the excitation current for each excitation period, in which the rising detection circuit outputs a control signal that turns on the switch during the period from the excitation period start point to the rising point of the excitation current, and turns off the switch during the period from the rising point to the excitation period end point.

According to the disclosure, the first voltage during low-voltage excitation is supplied from the DC/DC converter, and the feedback voltage to the DC/DC converter is set to the anode side voltage of the first backflow prevention diode, which makes it possible to control the first voltage to the minimum required for various series resistance values of the excitation coil, and to suppress heat generation in the constant current circuit. Therefore, in this disclosure, it is possible to improve the S/N ratio of the flow signal by increasing the excitation current, and to achieve miniaturization of the constant current circuit and miniaturization through removal of a heat dissipation mechanism. Additionally, in this disclosure, by setting the feedback voltage to the DC/DC converter to the anode side voltage of the first backflow prevention diode, a feedback operation free of influence of the back electromotive force of the excitation coil or external noise is possible.

### BRIEF DESCRIPTION OF THE DRAWINGS

FIG. 1 is a circuit diagram showing the configuration of an excitation circuit of an electromagnetic flowmeter according to an embodiment of the disclosure.

FIG. 2A and FIG. 2B are diagrams showing the voltage distribution of the drain-source voltage of a power MOS-FET and the voltage of an excitation coil in the excitation circuit according to an embodiment of the disclosure.

FIG. 3 is a diagram showing the voltage and current waveforms at various parts of an excitation circuit in the related art.

FIG. 4 is a diagram showing the voltage and current waveforms at various parts of the excitation circuit according to an embodiment of the disclosure.

FIG. 5 is an excitation circuit of an electromagnetic flowmeter in the related art.

FIG. 6A and FIG. 6B are diagrams showing the voltage distribution of the drain-source voltage of a power MOS-FET and the voltage of an excitation coil in an excitation circuit of an electromagnetic flowmeter in the related art.

### DESCRIPTION OF THE EMBODIMENTS

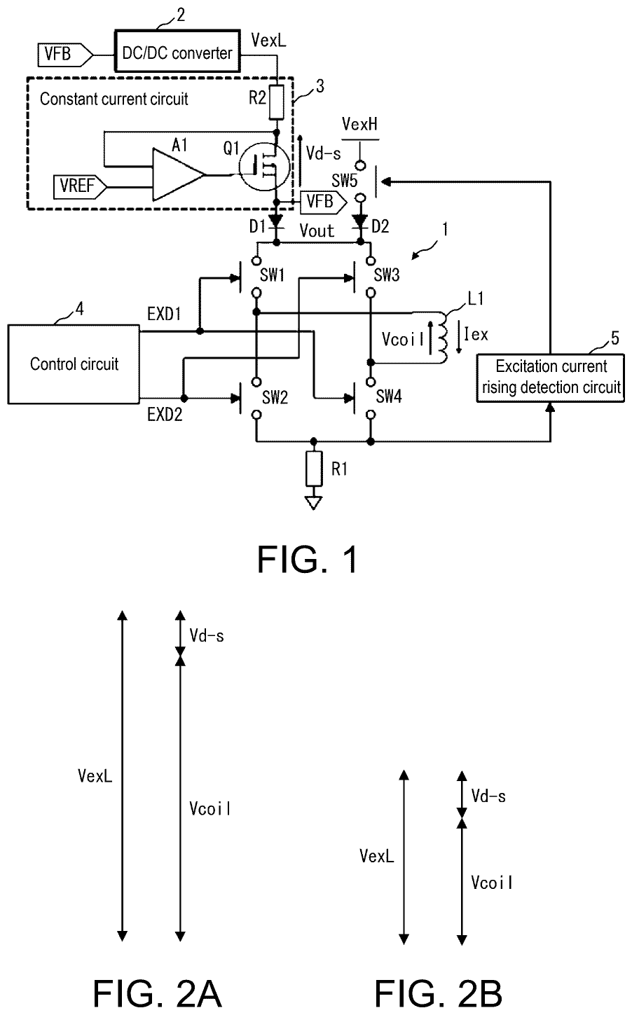

The following describes an embodiment of the disclosure with reference to the figures. FIG. 1 is a circuit diagram showing the configuration of an excitation circuit of an electromagnetic flowmeter according to an embodiment of the disclosure. The excitation circuit of the electromagnetic flowmeter includes: an excitation switching circuit 1 that switches the polarity of the excitation current supplied to an excitation coil L1 of the electromagnetic flowmeter to positive polarity/negative polarity for each positive/negative excitation period that is repeated at a constant cycle; backflow prevention diodes D1 and D2 with the cathodes connected to the voltage input terminal (Vout) of the excitation switching circuit 1; a current detection resistor R1 with one end connected to the ground side terminal of the excitation switching circuit 1 and the other end connected to ground; a DC/DC converter 2 that supplies a low voltage VexL (first voltage); a constant current circuit 3 with the input terminal connected to the output terminal of the DC/DC converter 2, and the output terminal connected to the anode of the backflow prevention diode D1; a control circuit 4 that outputs polarity switching signals EXD1 and EXD2 for the excitation current Iex; a switch SW5 with the first contact terminal connected to a high voltage VexH (second voltage) higher than the low voltage VexL, and the second contact terminal connected to the anode of the backflow prevention diode D2, which turns on during the period from an excitation period start point to a rising point of the excitation current Iex within the excitation period, and turns off during the period from the rising point to an excitation period end point; and an excitation current rising detection circuit 5 that outputs a control signal which turns on the switch SW5 during the period from the excitation period start point to the rising point of the excitation current Iex, and turns off the switch SW5 during the period from the rising point to the excitation period end point.

The excitation switching circuit 1 includes: a switch SW1 with the control terminal receiving the polarity switching signal EXD1, the first contact terminal connected to one end of the excitation coil L1 of a detector, and the second contact terminal connected to the voltage input terminal (Vout) of the excitation switching circuit 1; a switch SW2 with the control terminal receiving the polarity switching signal EXD2 that is complementary to the polarity switching signal EXD1, the first contact terminal connected to one end of the excitation coil L1, and the second contact terminal connected to the ground side terminal (one end of the current detection resistor R1) of the excitation switching circuit 1; a switch SW3 with the control terminal receiving the polarity switching signal EXD2, the first contact terminal connected to the other end of the excitation coil L1, and the second contact terminal connected to the voltage input terminal of the excitation switching circuit 1; and a switch SW4 with the control terminal receiving the polarity switching signal EXD1, the first contact terminal connected to the other end of the excitation coil L1, and the second contact terminal connected to the ground side terminal of the excitation switching circuit 1.

The excitation switching circuit 1 has a function to switch the polarity of the excitation current Iex supplied to the excitation coil L1 to positive polarity/negative polarity for each positive/negative excitation period that is repeated at a constant cycle. Specifically, the switches SW1 and SW4 are switches that, in response to the polarity switching signal EXD1 having a significant value (the polarity switching signal EXD2 having an insignificant value), turn on to switch the excitation current Iex to positive polarity and apply the same to the excitation coil L1. The switches SW2 and SW3 are switches that, in response to the polarity switching signal EXD2 having a significant value (the polarity switching signal EXD1 having an insignificant value), turn on to switch the excitation current Iex to negative polarity and apply the same to the excitation coil L1.

The constant current circuit 3 has a function to convert the excitation current Iex supplied from the DC/DC converter 2 to the excitation coil L1 into a constant current.

Similar to the related art, the constant current circuit 3 includes: a current detection resistor R2 with one end connected to the output terminal of the DC/DC converter 2; a power MOS-FET Q1 with the drain connected to the other end of the current detection resistor R2 and the source connected to the output terminal of the constant current circuit 3; and an operational amplifier A1 with the output terminal connected to the gate of the power MOS-FET Q1, which compares the voltage at the other end of the current detection resistor R2 with a reference voltage VREF, and controls the power MOS-FET Q1 based on the obtained comparison result.

The excitation current rising detection circuit 5 takes the terminal voltage of the current detection resistor R1 as input, and has a function to detect the rising point of the excitation current Iex when switching from negative polarity to positive polarity, and the rising point of the excitation current Iex when switching from positive polarity to negative polarity. A specific configuration example of the excitation current rising detection circuit 5 has been disclosed in Patent Document 1. The excitation current rising detection circuit 5 outputs a control signal to turn on the switch SW5 during the period from the excitation period start point (the switching point of polarity of the excitation current Iex) to the rising point of the excitation current Iex.

As a result, the switch SW5 turns on during the period from the excitation period start point to the rising point of the excitation current Iex, that is, during the high-voltage excitation period, and turns off during the period from the rising point to the excitation period end point (the next switching point of polarity), that is, during the low-voltage excitation period. Therefore, during the high-voltage excitation period, the high voltage VexH is supplied to the excitation switching circuit 1 via the diode D2, and during the low-voltage excitation period when the switch SW5 is off, the low voltage VexL is supplied to the excitation switching circuit 1 via the constant current circuit 3 and the diode D1.

In this embodiment, the DC/DC converter 2 is used to make the low voltage VexL variable rather than a constant voltage as in the related art. In addition, to make the low voltage VexL variable according to the DC resistance value of the excitation coil L1, a configuration that provides feedback to the DC/DC converter 2 is adopted. Furthermore, a feedback voltage VFB to the DC/DC converter 2 is set to the anode side voltage of the backflow prevention diode D1 connected to the constant current circuit 3. The DC/DC converter 2 outputs the voltage VexL that is proportional to the feedback voltage VFB.

Feeding back the voltage VFB that varies according to the DC resistance value of the excitation coil L1 to the DC/DC converter 2 makes it possible to control the low voltage VexL according to the series resistance value of the excitation coil L1. This can control the low voltage VexL to the minimum required for various series resistance values of the excitation coil L1, thereby suppressing heat generation in the power MOS-FET Q1 of the constant current circuit 3. Thus, in this embodiment, it is possible to improve the S/N ratio of the flow signal by increasing the excitation current Iex, and to achieve miniaturization of the power MOS-FET and miniaturization through removal of a heat dissipation mechanism.

FIG. 2A shows the voltage distribution of the drain-source voltage Vd-s of the power MOS-FET Q1 and the voltage Vcoil of the excitation coil L1 in this embodiment when the DC resistance value of the excitation coil L1 is large, and FIG. 2B shows the voltage distribution in this embodiment when the DC resistance value of the excitation coil L1 is small. It should be noted that in FIG. 2A and FIG. 2B, the residual voltage components such as the forward voltage drop of the diode D1 and the voltage drop due to the current detection resistors R1 and R2 are ignored. According to FIG. 2A and FIG. 2B, the voltage Vcoil of the excitation coil L1 becomes small when the DC resistance value of the excitation coil L1 is small, but in this embodiment, the voltage VexL also becomes small. Therefore, the drain-source voltage Vd-s of the power MOS-FET Q1 does not become large, making it possible to suppress heat generation in the power MOS-FET Q1.

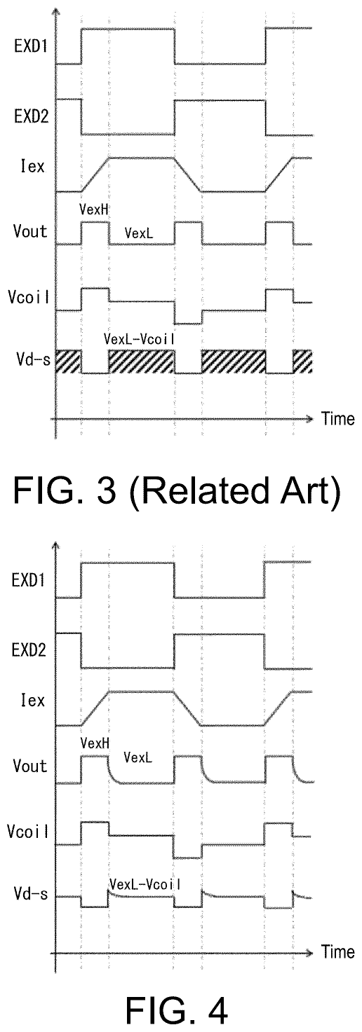

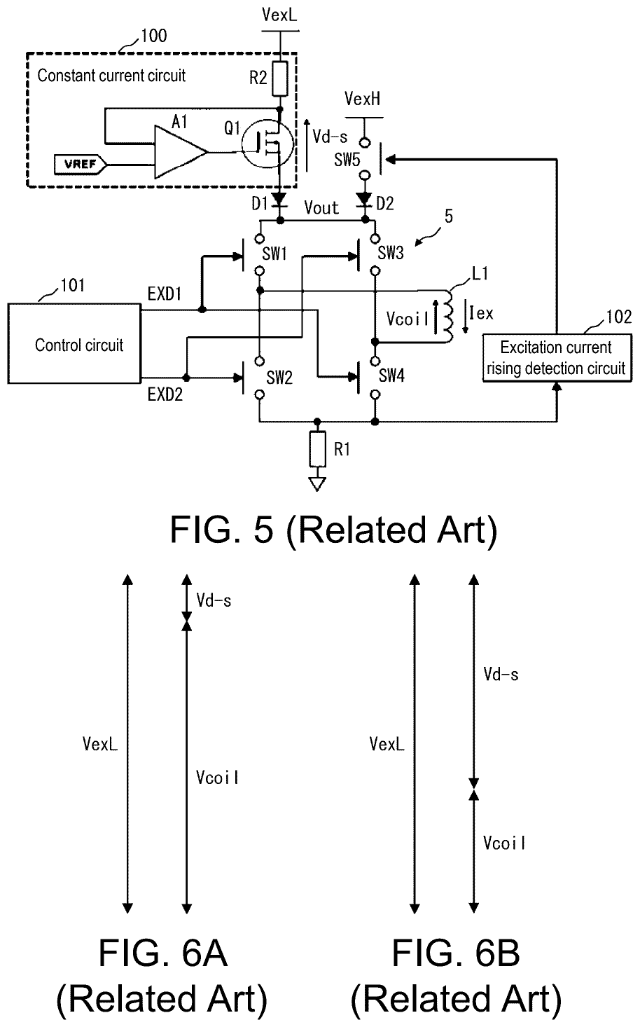

FIG. 3 shows the voltage waveforms of the polarity switching signals EXD1 and EXD2, the waveform of the excitation current Iex, the waveform of the cathode voltage Vout of the diodes D1 and D2, the waveform of the voltage Vcoil of the excitation coil L1, and the waveform of the drain-source voltage Vd-s of the power MOS-FET Q1 in the excitation circuit of the related art shown in FIG. 5. If the DC resistance value of the excitation coil L1 is R, during low-voltage excitation, the voltage Vcoil of the excitation coil L1 becomes R×Iex. Therefore, in the case where the DC resistance value R is small, the voltage Vcoil becomes small. The drain-source voltage Vd-s of the power MOS-FET Q1 during low-voltage excitation becomes VexL-Vcoil. Accordingly, in the case where the voltage Vcoil is small, the drain-source voltage Vd-s becomes large, resulting in greater heat generation in the power MOS-FET Q1. The hatched area in the Vd-s waveform in FIG. 3 contributes to heat generation.

FIG. 4 shows the voltage waveforms of the polarity switching signals EXD1 and EXD2, the waveform of the excitation current Iex, the waveform of the cathode voltage Vout of the diodes D1 and D2, the waveform of the voltage Vcoil of the excitation coil L1, and the waveform of the drain-source voltage Vd-s of the power MOS-FET Q1 in this embodiment. In this embodiment, in response to switching to low-voltage excitation, control is performed to reduce the voltage VexL to the minimum value required. Through this control, in the case where the voltage Vcoil of the excitation coil L1 is small, the voltage VexL also lowers, making it possible to reduce the drain-source voltage Vd-s of the power MOS-FET Q1. Therefore, it becomes possible to suppress heat generation in the power MOS-FET Q1.

Additionally, in this embodiment, the feedback voltage VFB to the DC/DC converter 2 is set to the anode side voltage of the backflow prevention diode D1 of the constant current circuit 3, so a feedback operation free of influence of the back electromotive force of the excitation coil L1 or external noise is possible.

What is claimed is:

1. An excitation circuit of an electromagnetic flowmeter, comprising:
an excitation switching circuit configured to switch polarity of an excitation current supplied to an excitation coil of the electromagnetic flowmeter to positive polarity/negative polarity for each positive/negative excitation period that is repeated at a constant cycle;
a first backflow prevention diode and a second backflow prevention diode with cathodes connected to a voltage input terminal of the excitation switching circuit;
a DC/DC converter configured to supply a first voltage;
a constant current circuit with an input terminal connected to an output terminal of the DC/DC converter, and an output terminal connected to an anode of the first backflow prevention diode; and
a switch with a first contact terminal connected to a second voltage higher than the first voltage, and a second contact terminal connected to an anode of the second backflow prevention diode, and configured to turn on during a period from an excitation period start point to a rising point of the excitation current within the excitation period, and to turn off during a period from the rising point to an excitation period end point,
wherein a feedback voltage to the DC/DC converter is set to an anode side voltage of the first backflow prevention diode.

2. The excitation circuit of the electromagnetic flowmeter according to claim 1, wherein the constant current circuit comprises:
a current detection resistor with one end connected to the output terminal of the DC/DC converter;
a transistor with a drain connected to the other end of the current detection resistor, and a source connected to the output terminal of the constant current circuit; and
an operational amplifier with an output terminal connected to a gate of the transistor, and configured to compare a voltage at the other end of the current detection resistor with a reference voltage, and to control the transistor based on a comparison result obtained.

3. The excitation circuit of the electromagnetic flowmeter according to claim 1, further comprising a rising detection circuit configured to detect the rising point of the excitation current for each excitation period,
wherein the rising detection circuit outputs a control signal that turns on the switch during the period from the excitation period start point to the rising point of the excitation current, and turns off the switch during the period from the rising point to the excitation period end point.
